(19) United States
(12) Patent Application Publication
(10) Pub. No.: US 2008/0217652 A1
(43) Pub. Date: Sep. 11, 2008

(54) Growth of AsSb-Based Semiconductor Structures on InP Substrates Using Sb-Containing Buffer Layers

(76) Inventors: Keh-Yung Cheng, Champaign, IL (US); Bing-Ruey Wu, Santa Rosa, CA (US)

Correspondence Address: GREENLEE WINNER AND SULLIVAN P C, 4875 PEARL EAST CIRCLE, SUITE 200, BOULDER, CO, 80301, US

(21) Appl. No.: 11/877,206

(22) Filed: Oct. 23, 2007

Related U.S. Application Data
(60) Provisional application No. 60/862,690, filed on Oct. 24, 2006.

(51) Int. Cl. H01L 29/267; H01L 21/205

(52) U.S. Cl. 257/190; 438/478; 257/E21.108; 257/E29.081

(57) ABSTRACT

This invention provides high quality and low defect density Sb-containing alloys on lattice-mismatched substrates using Sb-containing buffer layers. More specifically, provided is a method of forming an epitaxial semiconductor alloy on a substrate, comprising: providing a substrate (such as InP); growing an Sb-containing buffer layer on the substrate; and growing a layer of As/Sb-containing semiconductor alloy on the buffer layer.

### CROSS-REFERENCE TO RELATED APPLICATIONS

This application claims priority from U.S. provisional application No. 60/862,690, filed Oct. 24, 2006, which is hereby incorporated by reference to the extent not inconsistent with the disclosure herewith.

### STATEMENT REGARDING FEDERALLY SPONSORED RESEARCH OR DEVELOPMENT

This invention was made with U.S. government support under grant number HR0011-04-0034 awarded by Defense Advanced Research Projects Agency/Microsystems Technology Office. The U.S. government has certain rights in the invention.

### BACKGROUND OF THE INVENTION

Compound semiconductors with lattice constant around 6.1 Å have drawn much attention in recent years. The 6.1 Å binary alloy family includes InAs, GaSb, and AlSb, which have the lattice constants of 6.058 Å, 6.096 Å, and 6.136 Å, respectively. In addition to the binary alloys, ternary, quaternary and higher complexity semiconductor materials are desirable. Transport devices such as high electron mobility transistors (HEMT), made using combinations of these alloys, have the advantages of low power consumption and high speed. One of the most important advantages of these materials is high electron mobility. For example, the electron mobility in high purity InAs can reach 30000 cm²/V-s at room temperature, while the room temperature electron mobility of InSb can reach 78000 cm²/V-s, atop all the other compound semiconductors. This high electron mobility makes these materials good candidates for high-speed and low-power electronic applications, such as portable electronics.

Despite the excellent characteristics of these alloys, there is no semi-insulating substrate with a lattice constant around 6.1 Å. Therefore, it is difficult to prepare useful structures. There are some methods described to prepare semiconductor surfaces, but each of the methods currently used has drawbacks. One of the currently-used methods to prepare substrates is growing InAs on GaAs substrate with a thick buffer layer (more than 2 μm) to overcome the large lattice mismatch between GaAs and InAs. This method requires thick buffer layers and requires an extended growth time, and even with these techniques, the goal of reducing defect density varies for different growth techniques.

US patent application publication 2006/0017063 describes a metamorphic buffer constructed of multiple layers that transition from a smaller lattice constant close to that of the substrate to layers that have a larger lattice constant close to that of the device. The layered structures described have considerable thickness such as 15 μm. U.S. Pat. No. 5,770,868 describes a GaAs substrate, a compositionally graded metamorphic buffer layer and an indium-containing semiconductor, where the buffer layer has lattice constants which transition from the lattice constant of the substrate material to the semiconductor material. US patent application publication 2006/0076577 describes a multi-layered structure having a substrate, a buffer layer, and several mixed composition layers separating the buffer layer from the surface for channeling electrons.

There are limitations of each of the methods currently used to prepare semiconductor structures having lattice constants around 6.1 Å. An improved method for producing high-quality semiconductor alloys is needed.

### BRIEF SUMMARY OF THE INVENTION

This invention provides an improved method for preparing high quality and low defect density Sb-containing alloys on lattice-mismatched substrates using Sb-containing buffer layers.

More specifically, provided is a method of forming an epitaxial semiconductor alloy on a substrate, comprising: providing a substrate (such as InP); growing an Sb-containing buffer layer on the substrate; and growing a layer of desired semiconductor on the buffer layer. The Sb-containing buffer layer is further described herein.

The substrate and desired semiconductor are lattice-mismatched. Some useful substrates include: InP, GaAs, silicon, Ge or GaP. The substrate is usually a single crystal wafer with a thickness in the range of 100-500 μm (or more) that provides a desired lattice constant, desired electrical and optical properties, and mechanical stability. If desired, non-single crystal substrates can be used. Determination of the desired thickness and composition of the substrate is well known in the art.

In one embodiment, the Sb-containing buffer layer comprises a first layer of AlₓGa₍₁₋ₓ₎AsSb and a second layer of Al(In)Sb, where x is selected from 1 to 0. In one embodiment, x=1 and the first layer of the Sb-containing buffer layer is AlAsSb. In one embodiment, x can not be 0. By adding Ga to the AlAsSb layer, the lattice constant is not affected, but the energy bandgap will change. Al and Ga are both in column III of the periodic table, and therefore, they share the same lattice positions in the crystal. The AlGaAsSb layer has a fixed As to Sb ratio so that the lattice constant is fixed to match the substrate, but the Al and Ga can change from pure Al, to a mixture of Al and Ga, to pure Ga, as known in the art. As known in the art, in a AlGaAsSb layer, the proportion of Al:Ga can be selected to produce the desired properties without undue experimentation. All useful proportions are intended to be included here to the extent as if they were individually listed. When “AlGaAsSb” is used herein, it is understood that Ga may or may not be present. The amount of As:Sb is selected, as known in the art, to produce the desired function without undue experimentation.

In one embodiment, an AlGaAsSb/AlSb buffer layer is grown on an InP substrate, followed by a layer of desired semiconductor, such as InAsSb. In one embodiment, the desired semiconductor is InAs_{0.8}Sb_{0.2}.

The Sb-containing buffer layer is used to allow the semiconductor layer to grow on the substrate. The Sb-containing buffer layer has a thickness and composition which allow the formation of a semiconductor surface having the desired properties. In one example of the invention, the Sb-containing buffer layers are thinner than those currently used. In one embodiment, the buffer layer is ≦1 μm thick. In one embodiment, the buffer layer has a thickness of about 1 μm. In one embodiment, the Sb-containing buffer layer has a total thickness of between 0.5 μm and 3 μm. In one embodiment, the Sb-containing buffer layer has two layers, an AlGaAsSb and an Al(In)Sb layer. Other compositions of the buffer layer or layers are useful, and such compositions can be determined by one of ordinary skill in the art without undue experimentation. In one embodiment, the AlGaAsSb layer is lattice-matched to the substrate, while the Al(In)Sb layer is lattice matched to the final epitaxial layer, but is lattice mismatched to AlGaAsSb. In one embodiment, the Al(In)Sb layer thickness is between 0 and 3 μm. The buffer layer may also contain only one layer, with a lattice constant that is intermediate between the substrate and semiconductor layer. In one embodiment, the buffer layer is between 0 and 20000 Å AlSb and between 500-5000 Å InAsSb. All intermediate values and ranges of any range given herein is intended to be incorporated to the extent as if they were individually listed.

In one embodiment, the As/Sb-containing semiconductor alloy layer contains both As and Sb. The semiconductor alloy layer may further comprise one or more element from Groups III and/or Group V. Some particular semiconductor alloys include InAsSb, GaAsSb, InGaAsSb, InGaAlAsSbP, and AlGaInAsSb. The semiconductor alloy layer may have any desired thickness, such as from 200 Å to 2 μm, depending on the device structure, as known in the art. Group III elements include Al, Ga, In. Group V elements include As, P, Sb. As used in the art, alloys are those having formulas such as: InₓGa₁₋ₓAs, where x is the proportion of InAs and (1-x) is the proportion of GaAs. All alloys that are usable in the invention with proportions that are not specifically listed are included herein to the extent as if they were individually listed. The particular chemical structure may be not specified in the disclosure—this indicates that all suitable alloy compositions are intended to be included to the extent as if they were individually listed.

In one embodiment, the growth of AlGaAsSb on InP first as part of the buffer layer achieves smooth mismatched growth interface without a 3D transition. Without this layer, even if Sb or Sb-compounds are used, the layer will start with 3D growth and then gradually change to 2D growth.

In one embodiment, the semiconductor has an electron mobility over 10,000 cm²/V-s. In one embodiment, the semiconductor has a room temperature electron mobility over 15,000 cm²/V-s. In one embodiment, the substrate has a room temperature electron mobility over 12,000 cm²/V-s. In one embodiment, the substrate has a room temperature electron mobility over 14,000 cm²/V-s.

Also provided are semiconductor devices and substrates as described herein.

As used herein, “layer” does not mean that a perfect layer is formed without defects. Rather, as known in the art, certain defects such as dislocations and antiphase domains may be present, as long as the defects do not prevent the layer from having the desired characteristics. Also, “layer” does not necessarily mean that a smooth surface is formed. There may be portions of the layer which contain additional thickness than other portions of the layer.

As used herein, “lattice match” is not meant to indicate that the lattice constant of substances are exactly the same, but rather, the lattice constants are close to each other. It is preferred that the lattice constants of lattice matched substances are as close as possible, preferably within ±0.1%, to allow the best growth characteristics and resulting products, among other reasons known in the art. As used herein, “lattice mismatch” means that the lattice constants of substances do not fall within the values or ranges used for “lattice match”. Some examples of lattice mismatch are those lattice constants that are greater or equal than ±1% of each other. One layer sandwiched between two layers can be lattice matched to one layer and lattice mismatched to the other layer. For example, in one example, the Al(In)Sb layer of the buffer layer is lattice matched to the final epitaxial layer, but lattice mismatched to the AlGaAsSb (or AlAsSb) layer of the buffer layer. All intermediate values and ranges in the ranges of are intended by be included to the extent as if they were specifically listed.

For many applications, it is desirable for the semiconductor device to have an active region with a lattice constant in the 6.05-6.35 angstrom range. For example, the active region may be based on ternary or quaternary compounds where the constituent elements are selected from aluminum (Al), indium (In), arsenic (As), gallium (Ga), phosphorus (P) and antimony (Sb) and combinations thereof. For many applications, InAsSb metamorphic buffer layers are useful.

### BRIEF DESCRIPTION OF THE FIGURES

FIG. 1 shows the [110] and [1 1̅0] reflection high-energy electron diffraction (RHEED) patterns of (a) AlAsSb growth on InP substrate, and (b) the growth of InAsSb on AlAsSb surface of part (a).

FIG. 2 shows X-ray diffraction (XRD) rocking curves of InAsSb/AlSb/AlAsSb/InP samples with 3000 Å AlSb (solid squares) and 1 μm AlSb (open circles). The detailed layer structure is shown in the inset.

FIG. 3 shows etch pit density (EPD) of InAsSb samples with different AlSb buffer layer thicknesses. The left inset image shows the etched surface of the InAsSb sample without AlSb buffer and the right inset image shows the etched surface of the InAsSb sample with a 1 μm AlSb buffer layer.

FIG. 4 shows the electron mobility of the unintentionally doped InAsSb samples with different AlSb buffer layer thicknesses.

FIG. 5 provides a flow chart describing one embodiment of the process described herein.

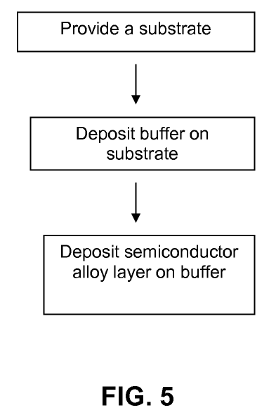

FIG. 6 shows dark field cross-sectional TEM images of (a) the AlSb grown on 1000 Å AlAs_{0.5}Sb_{0.5}, and (b) a 2000 Å InAs_{0.8}Sb_{0.2} grown on 8000 Å AlSb/1000 Å AlAs_{0.5}Sb_{0.5} bi-layer buffer layer structure. A high density of threading dislocations is clearly seen at the interface in AlSb in (a).

FIG. 7 shows the room temperature electron mobility of InAs_{0.8}Sb_{0.2} grown on InP substrate as a function of AlSb/AlAs_{0.5}Sb_{0.5} buffer layer thickness. The buffer layer structure consists of an AlAs_{0.5}Sb_{0.5} with a fixed thickness of 1000 Å and an AlSb of various thicknesses. The thickness and growth temperature of InAs_{0.8}Sb_{0.2} are fixed at 2000 Å and 360° C., respectively.

FIG. 8 shows the room temperature electron mobility of 2000 Å thick InAs_{0.8}Sb_{0.2} grown at different temperatures on AlSb/AlAs_{0.5}Sb_{0.5}/InP. The bi-layer buffer layer structure consists of an 8000 Å AlSb and a 1000 Å AlAs_{0.5}Sb_{0.5} for all samples.

### DETAILED DESCRIPTION OF THE INVENTION

The description herein is intended to provide non-limiting examples of the invention to aid in understanding.

It is commonly recognized that as epitaxial growth proceeds in a lattice-mismatched system, misfit energy between layers is initially accommodated elastically until the epitaxial layer exceeds a critical thickness. Beyond this value, the elastically accommodated misfit energy is partially relieved through the formation of misfit dislocations along the hetero-interface. Furthermore, if the mismatch strain is large, three-dimensional (3D) islanding formation precedes defects generation, which prevents the layer-by-layer epitaxial growth of device quality structures. The 3D islanding at the hetero-interface also causes threading dislocations to skew and leads to an inefficient defect cancellation process. In general, a high density of threading dislocations exists in the epitaxial layer of a mismatched material system, which degrades device performance and contributes to reliability problems.

Growing 6.1 Å family compound semiconductor alloys on InP substrates offers several key advantages over growing them on GaAs substrates. First, the lattice mismatch between InP substrate (lattice constant=5.869 Å) and 6.1 Å is only ˜50% of that between GaAs substrate (lattice constant=5.653 Å) and 6.1 Å. Second, the thermal conductivity of InP is twice higher than that of GaAs, which provides more protection to the Sb-compound from overheating.

The success of this method relies on the design of a surface structure engineered buffer layer such that a 2D growth front is provided on the epilayer. The other important advantage of this method is that semi-insulating surface structure engineered templates are readily available for high-speed designs. Since this unique method does not require any ex-situ process steps to prepare the surface structure engineered buffer layer(s), the whole growth process can be accomplished in a single molecular beam epitaxy (MBE) growth run. Therefore, the methods described here can be used to grow high-quality InSb/InAs-based high-mobility semiconductor alloys on lattice-mismatched semiconductors, including silicon, suitable for CMOS applications.

### Methods

The heterostructure growth mode is monitored through the observation of reflection high-energy electron diffraction (RHEED) patterns during the MBE growth. The defect density and residual strain of the grown materials are analyzed using high-resolution x-ray diffraction (XRD) spectroscopy and transmission electron microscopy (TEM), respectively. The electrical and optical properties of the epilayer are analyzed using Hall effect and photoluminescence measurements, respectively. Surface structure engineered templates can be developed for application to heterostructures with large lattice-mismatches such as InAs-on-Si using the methods described herein. Known defect reduction techniques such as thermal cycling as well as inserting strained superlattices can be used to minimize the defect density. Since a 2D growth mode is maintained in the methods described herein, either procedure is very efficient in reducing the defect density even in thin layer structures. The surface structure engineered heterogeneous integration method described herein can be used to integrate III-V alloys on silicon platforms.

The methods described herein are used to grow, fabricate and characterize high-speed device structures utilizing bulk Sb-based alloys and two-dimensional electron gas structures. The materials and methods described herein are useful in both the silicon industry and the high-speed electronics field, as well as other applications, as known in the art.

### Experiment One

The buffer layer for the growth of 6.1 Å family alloys on InP substrates in this example was a 1000 Å AlAs_{0.56}Sb_{0.44} layer lattice matched to InP, and an AlSb layer. The AlSb layer thickness varied from 0 to 1 μm. On top of the buffer layer, a 1000 Å InAsSb layer lattice matched to AlSb was grown. The electrical property of the top InAsSb layer was evaluated using Hall measurements. XRD was used to characterize the structural property and the etch pit density (EPD) study was used to measure the defect density in the InAsSb layer.

The growths were carried out in a gas-source molecular beam epitaxy system equipped with a 2200 l/s turbopump and a 9000 l/s cryopump. Samples were grown on nominally exact (001) InP:Fe semi-insulating substrates. Arsine and phosphine were used as arsenic and phosphorous sources, respectively, and a solid antimony cracker cell with adjustable precision valve was used as the antimony source. Standard effusion cells were used to provide elemental group III fluxes. The group III deposition rate was calibrated by the intensity oscillations of the RHEED patterns. The growth temperature was chosen at 35° C. below the passivated InP surface oxide desorption temperature (Td). In this study, the passivated InP surface oxide desorption temperature was about 535° C.

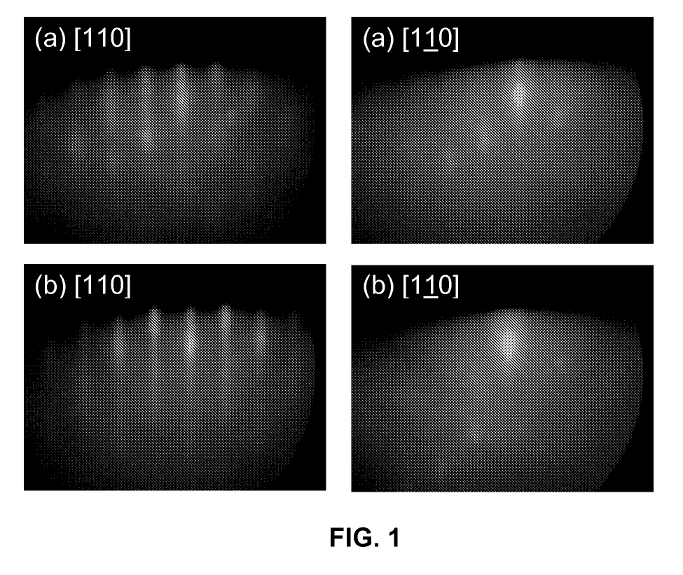

After depositing the 1000 Å AlAs_{0.56}Sb_{0.44} layer lattice matched to InP, the surface displayed a streaky (1×3) RHEED pattern, as shown in FIG. 1 (a). During the growth of InAsSb on top of the AlAsSb layer, the RHEED pattern changed from streaky (1×3) to streaky (2×3) as shown in FIG. 1. No spotty RHEED pattern was observed even when the growth was interrupted for 60 seconds after a 2.4 monolayer (ML) of InAsSb was deposited. Despite the fact that the InAsSb layer, which is lattice matched to AlSb, has a large lattice mismatch (3.9%) to AlAsSb, the streaky RHEED pattern transition indicated that the InAsSb was grown under a two-dimensional growth mode, or the Frank-van der Merwe (FM) mode. When AlSb was inserted between InAsSb and AlAsSb, the RHEED pattern remained streaky, even when the AlSb thickness was as thick as 1 μm. Unlike AlSb buffer grown on GaAs, where three dimensional growths always occur first then transformed into the two-dimensional growth mode, AlSb/AlAsSb buffer layer growth is always under two-dimensional or FM growth mode.

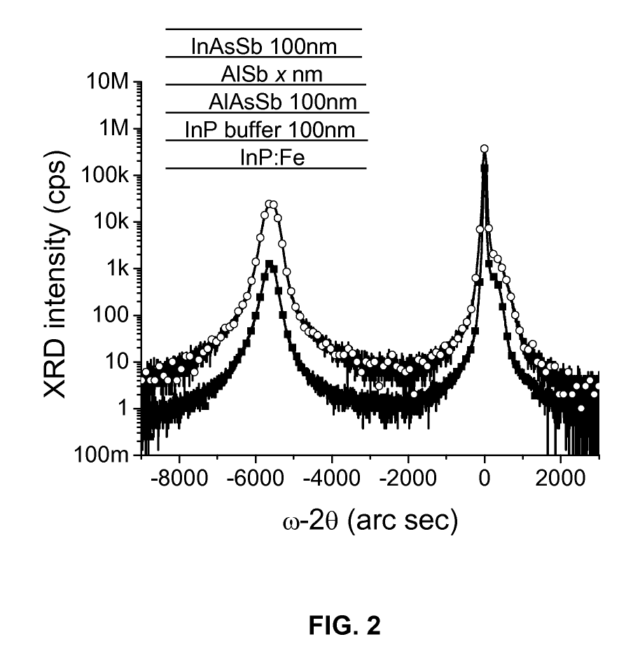

The XRD rocking curves in the (004) reflection geometry of the 1000 Å InAsSb samples are shown in FIG. 2. The inset shows the detailed layer structure of samples with different AlSb buffer layer thicknesses. The upper curve (open circles) is the sample with a 1 μm AlSb buffer layer and the lower curve (solid squares) is the sample with a 3000 Å AlSb buffer layer. The AlAsSb layer in both samples is 1000 Å. The lattice mismatch of the AlAsSb layer in both samples was controlled within 500 arc seconds relative to the InP substrate peak. The peak on the compressive side of the XRD spectra is the InAsSb/AlSb peak. The symmetric shape of the peaks indicates the high structural property of the InAsSb/AlSb layers and indicates that the InAsSb layers are lattice matched to AlSb. The measured XRD rocking curves in both (004) and (115) reflection geometries show that the complete relaxation has been achieved in the 1000 Å thick InAsSb layers, and the As composition in InAs_{y}Sb_{1-y} is about 77%.

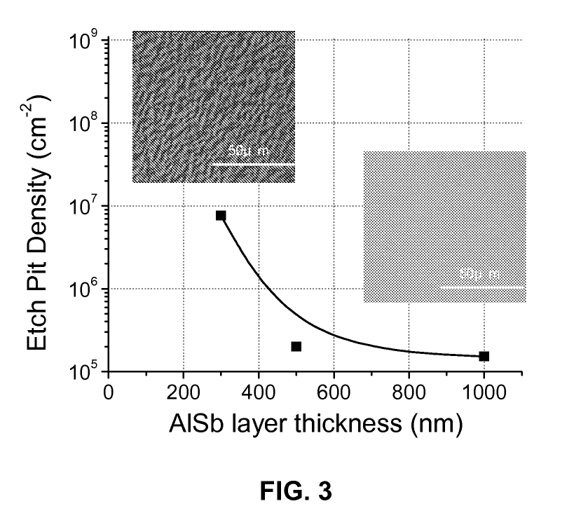

Since in some of the samples the defect density was too low to be studied using cross-sectional transmission electron microscopy, it was measured by counting the EPD on the InAsSb surface as shown in FIG. 3. The EPD study was conducted using HCl as the etching solution. The image of the optical microscopy showed that the etched InAsSb surface directly grown on AlAsSb buffer layer without AlSb was very rough, as shown as the left inset of FIG. 3. The EPD of this sample is estimated over 10⁹ cm⁻². By inserting a 3000 Å AlSb buffer layer beneath the InAsSb layer, the EPD dropped rapidly to 7.5×10⁶ cm⁻². The EPD of the InAsSb layer dropped further to ˜2×10⁵ cm⁻² by increasing the AlSb buffer layer thickness to 5000 Å. Further increasing the AlSb thickness to 1 μm did not significantly reduce the EPD of the InAsSb layer. The surface morphology of the etched surface on the 1 μm AlSb buffer layer is shown as the right inset of FIG. 3.

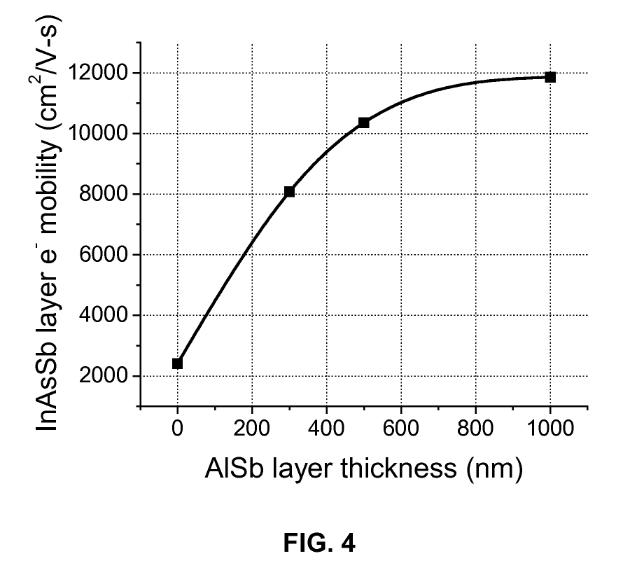

The electron mobility of the 1000 Å InAsSb samples with different AlSb buffer layer thicknesses grown on 1000 Å AlAsSb was measured using Hall measurements. The results are shown in FIG. 4. The electron mobility increases from ˜2500 cm²/V-s without using the AlSb buffer layer to ˜12000 cm²/V-s with a 1 μm AlSb buffer layer. Since both AlSb and AlAsSb are semi-insulating and the layers were grown on semi-insulating InP substrates, the electron conduction occurs only in the InAsSb layer. In samples with no or thin (<3000 Å) AlSb buffer layer, the high density of misfit dislocations near the AlSb/AlAsSb interface used to release the misfit strains reduce the electron mobility significantly. The AlSb buffer layer turns out to be an efficient misfit dislocation filter. With only a 5000 Å of AlSb buffer layer, the dislocation density decreases drastically, and the electron mobility increases accordingly, even though the InAsSb is only 1000 Å thick. The electron mobility can be further improved by further increase the InAsSb layer thicker. Antimony has been used in compliant epitaxy acting as a surfactant to suppress the three-dimensional growth. (Thin Solid Films 321 (1998) 125-130). It is believed that the antimony atoms tend to segregate at the growth front and reduce the surface diffusion length of surface atoms. When growing InAsSb/AlAsSb or InAsSb/AlSb/AlAsSb heterostructures, the Sb-related surfactant effect dominates the surface reaction and leads to the layer-by-layer FM growth mode. This reaction was observed as streaky RHEED patterns displayed through out the growth process. Although the layers were grown two-dimensionally, high density of misfit dislocations have to form in order to accommodate the 3.9% strain between InAsSb/AlSb and InP. Therefore, in the unintentionally doped InAsSb layer, the EPD reduces significantly and the electron mobility enhances greatly with increasing AlSb thickness. Furthermore, it is plausible to grow 6.1 Å family alloy-based optoelectronic devices on InP substrates rather than GaAs substrates since the lattice mismatch between InP and 6.1 Å family alloys is almost half of that between GaAs and 6.1 Å family alloys. In addition, the thermal conductivity of InP is twice higher than that of GaAs, which provides more protection to the Sb-compound from overheating.

This experiment shows growing 6.1 Å family compound semiconductor alloys on semi-insulating InP substrates. The InAsSb/AlSb/AlAsSb/InP layer structure ensures the high electronic and structural properties and low EDP in the InAsSb layer on an AlSb buffer layer as thin as 1 μm. This can greatly enhance the device performance of optoelectronic devices using 6.1 Å family compound semiconductor alloys.

### Experiment Two

The epitaxial growth was carried out in a gas-source molecular beam epitaxy system. Arsine (AsH₃) and phosphine (PH₃) injected though high temperature crackers were used to generate As₂ and P₂, respectively. Mass flow controllers were used to adjust the flows of these two gases. Antimony molecular beam was supplied by thermally decomposing high purity antimony into Sb₂ via an antimony valved cracker. The Sb₂ flux was precisely controlled by a needle valve located at the front of the valved cracker. The substrate temperature was controlled and monitored by a thermal couple in contact with the backside of the sample holder. A pyrometer aiming at the center of the sample was used to measure the substrate temperature through a quartz view port on the growth chamber. During the growth, the RHEED patterns were used to monitor the status of the surface reconstructions.

Two-inch diameter epi-ready semi-insulating (001) InP substrates were cut into quarters and mounted on molybdenum pucks with high-purity indium. The epitaxial growth on InP substrates started with the surface oxide desorption process by heating the substrate up to about 480° C. under a P₂ overpressure. After desorption of surface oxide where a clear (2×8) streaky RHEED pattern was observed, the InP buffer layer was first grown, followed by a 1000 Å AlAs_{0.5}Sb_{0.5} lattice matched to InP. Following the AlAs_{0.5}Sb_{0.5} layer was an AlSb layer of different thicknesses, from 2000 to 16000 Å. Finally, the growth was concluded with a 2000 Å unintentionally doped InAs_{0.8}Sb_{0.2} active layer, which was grown under different substrate temperatures to optimize the electron mobility. One reference sample without the 1000 Å AlAs_{0.5}Sb_{0.5} buffer layer was also grown for comparison purpose.

After the growth, the lattice constants of the structure were determined by measuring the rocking curves of the grown structure in a Bede D1 high-resolution x-ray diffraction system. Hall measurements were carried out to determine the electron mobility and carrier concentration. Cross-sectional transmission electron microscopy (XTEM) was used to evaluate the microstructures of hetero-interfaces.

The lattice mismatch between AlAs_{0.5}Sb_{0.5} (lattice matched to InP, a=5.8686 Å) and AlSb (a=6.136 Å) is about 4.7%. Generally the two adjacent layers with such a large lattice mismatch will result in a change of growth mode from two-dimensional (2D) to three-dimensional (3D). As mentioned above, spotty RHEED patterns at the initiation of AlSb layer growth on AlAs_{0.5}Sb_{0.5} are expected. However, this was not observed during the AlSb/AlAs_{0.5}Sb_{0.5} growth transition. Instead, the RHEED patterns maintained the smooth streaky (1×3) patterns during the transition. The AlSb/AlAs_{0.5}Sb_{0.5} bi-layer buffer layer structure certainly provides a smooth 2D growth front, which could improve the electron mobility of the InAs_{0.8}Sb_{0.2} layer.

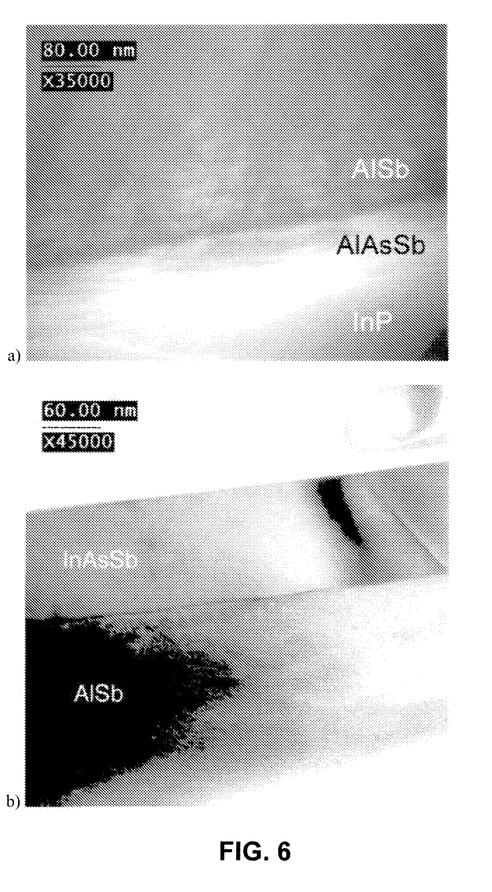

It is believed that antimony acts as a surfactant during epitaxial growth of lattice-mismatched hetero-layers to suppress the 3D growth and enhance a planar growth front. During the growth of antimony compounds, the antimony atoms have the tendency to segregate from the bulk forming a thin layer floating on the growth front. When growing the AlSb/AlAs_{0.5}Sb_{0.5} buffer layer structure, the antimony anion common to both layers acting as a surfactant and promoting a 2D growth front. This assessment is supported by the smooth streaky RHEED pattern observed during the transition between theses two layers. Even though the 2D growth mode was observed, the large lattice mismatch between AlSb/AlAs_{0.5}Sb_{0.5} and InP must be accommodated through the formation of dislocations. As expected, as shown in FIG. 6(a), the XTEM image of the AlSb/AlAs_{0.5}Sb_{0.5} interface shows a high density (>10¹⁰ cm⁻²) of threading dislocations. After the growth of 8000 Å of AlSb buffer layer, the threading dislocation density reduced dramatically and only very few are visible in XTEM images. FIG. 6(b) shows an XTEM image of the InAs_{0.8}Sb_{0.2}/AlSb interface, where one dislocation line is visible corresponding to a defect density of ˜10⁷ cm⁻². A 2000 Å InAs_{0.8}Sb_{0.2} sample grown under the optimized condition, to be discussed later, containing an 8000 Å AlSb/1000 Å AlAs_{0.5}Sb_{0.5} buffer layer structure shows a fairly high electron mobility of 15000 cm²/V-s. In contrast to the bi-layer buffer structure, when the AlSb buffer layer was grown directly on InP substrate, a spotty RHEED pattern appeared immediately at the inception of the AlSb growth indicating the formation of a 3D growth front. The 3D growth morphology will introduce extra defects and, thus, degrades the transport property of the top InAs_{0.8}Sb_{0.2} layer. Indeed, in a reference InAs_{0.8}Sb_{0.2} sample of 2000 Å thick grown under a similar condition but contains only a 9000 Å AlSb single buffer layer has a lower electron mobility of ˜13000 cm²/V-s. The improvement of the electron mobility of the thin InAs_{0.8}Sb_{0.2} layer indicates the effectiveness of inserting an AlAs_{0.5}Sb_{0.5} buffer layer in between the InP substrate and the AlSb buffer layer.

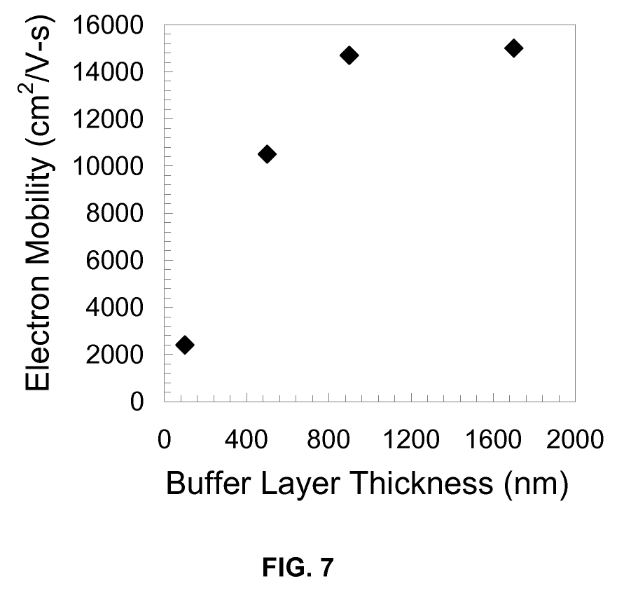

The improvement of the electron mobility of the InAs_{0.8}Sb_{0.2} layer was further studied by increasing the total buffer layer thickness. FIG. 7 shows the electron mobility improvement as the AlSb buffer layer thickness is increased while keeping the AlAs_{0.5}Sb_{0.5} layer thickness fixed at 1000 Å. A growth temperature of 360° C. was used for InAs_{0.8}Sb_{0.2} growth. When the AlSb buffer layer thickness increases from 1000 to 8000 Å, the corresponding electron mobility improves from 2000 to 15000 cm²/V-s. However, as the buffer layer thickness further increases to 16000 Å, the electron mobility does not improve further. One possible reason for the electron mobility saturation in InAsSb could be attributed to the finite impurity scattering from the unintentionally doped background impurities with a concentration near mid-to-high 10¹⁶ cm⁻³.

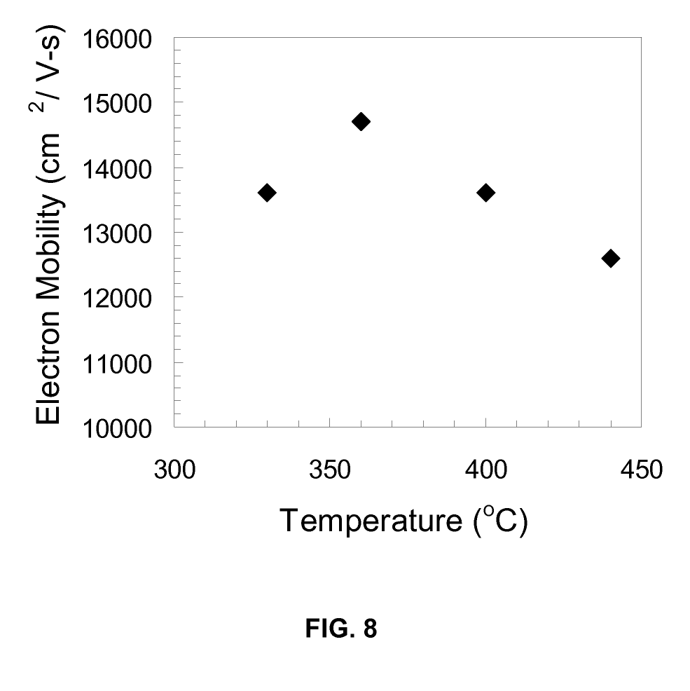

The electron mobility of InAs_{0.8}Sb_{0.2} layers was also studied through the growth temperature optimization. Using a fixed buffer layer structure of 8000 Å AlSb/1000 Å AlAs_{0.5}Sb_{0.5}, the measured electron mobility in the 2000 Å InAs_{0.8}Sb_{0.2} layers are shown in FIG. 8. It is clear that when the InAs_{0.8}Sb_{0.2} growth temperature is decreases from 445° C. to 360° C., the electron mobility increases from 12000 to about 15000 cm²/V-s. Further decreasing the growth temperature to 340° C. does not improve the electron mobility further. This result indicates that the electron mobility could be improved further by optimizing additional growth parameters such as the growth rate and V/III flux ratio. Modification of these parameters is easily carried out by one of ordinary skill in the art without undue experimentation.

The typical electron mobility at room temperature of bulk InAs with a donor concentration of 10¹⁷ cm⁻³ is about 16000 cm²/V-s. By adding Sb into InAs to form InAs_{0.8}Sb_{0.2}, which is lattice matched to AlSb, could enhance the electron mobility. However, due to the added alloy scatterings, the mobility improvement is expected to be limited. Since there are no reported mobility values of InAs_{0.8}Sb_{0.2}, the results of a HEMT device with an InAs_{0.8}Sb_{0.2} channel are compared instead. For the reported HEMT structure grown on a GaAs substrate using a 2.1 μm AlSb buffer layer, the electron mobility and sheet carrier density of the InAs_{0.8}Sb_{0.2} channel are 14000 cm²/V-s and 1.4×10¹² cm⁻², respectively. This is comparable to the room temperature electron mobility value of the unintentionally doped InAs_{0.8}Sb_{0.2} achieved in this study, which is 15000 cm²/V-s. Nevertheless, a thin AlSb/AlAs_{0.5}Sb_{0.5} bi-layer buffer structure of 9000 Å was used in this study.

When a group of substituents is disclosed herein, it is understood that all individual members of those groups and all subgroups, including any isomers and enantiomers of the group members, and classes of compounds that can be formed using the substituents are disclosed separately. When a compound is claimed, it should be understood that compounds known in the art including the compounds disclosed in the references disclosed herein are not intended to be included. When a Markush group or other grouping is used herein, all individual members of the group and all combinations and subcombinations possible of the group are intended to be individually included in the disclosure.

Every formulation or combination of components described or exemplified can be used to practice the invention, unless otherwise stated. Specific names of compounds are intended to be exemplary, as it is known that one of ordinary skill in the art can name the same compounds differently. When a compound is described herein such that a particular isomer or enantiomer of the compound is not specified, for example, in a formula or in a chemical name, that description is intended to include each isomers and enantiomer of the compound described individual or in any combination. One of ordinary skill in the art will appreciate that methods, device elements, starting materials, synthetic methods, and compositions other than those specifically exemplified can be employed in the practice of the invention without resort to undue experimentation. All art-known functional equivalents, of any such methods, device elements, starting materials, synthetic methods, and compositions are intended to be included in this invention. Whenever a range is given in the specification, for example, a temperature range, a time range, or a composition range, all intermediate ranges and subranges, as well as all individual values included in the ranges given are intended to be included in the disclosure.

As used herein, “comprising” is synonymous with “including,” “containing,” or “characterized by,” and is inclusive or open-ended and does not exclude additional, unrecited elements or method steps. As used herein, “consisting of” excludes any element, step, or ingredient not specified in the claim element. As used herein, “consisting essentially of” does not exclude materials or steps that do not materially affect the basic and novel characteristics of the claim. Any recitation herein of the term “comprising”, particularly in a description of components of a composition or in a description of elements of a device, is understood to encompass those compositions and methods consisting essentially of and consisting of the recited components or elements. The invention illustratively described herein suitably may be practiced in the absence of any element or elements, limitation or limitations which is not specifically disclosed herein.

The terms and expressions which have been employed are used as terms of description and not of limitation, and there is no intention in the use of such terms and expressions of excluding any equivalents of the features shown and described or portions thereof, but it is recognized that various modifications are possible within the scope of the invention claimed. Thus, it should be understood that although the present invention has been specifically disclosed by preferred embodiments and optional features, modification and variation of the concepts herein disclosed may be resorted to by those skilled in the art, and that such modifications and variations are considered to be within the scope of this invention as defined by the appended claims.

In general the terms and phrases used herein have their art-recognized meaning, which can be found by reference to standard texts, journal references and contexts known to those skilled in the art. The definitions are provided to clarify their specific use in the context of the invention. All patents and publications mentioned in the specification are indicative of the levels of skill of those skilled in the art to which the invention pertains. References cited herein are incorporated by reference herein in their entirety to indicate the state of the art, in some cases as of their filing date, and it is intended that this information can be employed herein, if needed, to exclude (for example, to disclaim) specific embodiments that are in the prior art. For example, when a structure is claimed, it should be understood that structures known in the prior art, including certain structures disclosed in the references disclosed herein (particularly in referenced patent documents), are not intended to be included in the claim. Unless otherwise indicated, all structures listed here (such as AlGaAsSb) include all useful embodiments of those structures, with varying amounts of the various elements, as known in the art. Unless otherwise indicated, the formulas used herein take their art-known meaning.

### REFERENCES

1. F. Genty, L. Cerutti, A. Garnache, E. Picard, E. Hadji, D. Romanini, F. Bournazaud, P. Grech, S. Gaillard, and C. Alibert, IEE Proc—Optoelectron., vol. 149, pp. 22, 2002.
2. J. B. Hacker, J. Bergman, G. Nagy, G. Sullivan, C. Kadow, H.-K. Lin, A. C. Gossard, M. Rodwell, and B. Brar, IEEE Microwave and Wireless Components Lett., vol. 14, pp. 156, 2004.
3. N. A. Papanicolaou, B. R. Bennett, J. B. Boos, D. Park, R. Bass, IEE Electron. Lett., vol. 41, pp. 1088, 2005.
4. H. Kroemer, Physica E, vol. 20, pp. 196, 2004.
5. R. Tsai, M. Barsky, J. Lee, J. B. Boos, B. R. Bennett, R. Magno, C. Namba, P. H. Liu, A. Gutierrez, R. Lai, Proc. IEEE Lester Eastman Conference on High Performance Devices, pp. 276, 2002.
6. H. C. Gatos and M. C. Lavine, Chemical Behaviour of Semiconductors: Etching Characteristics.
7. T. Sato, M. Akabori, and S. Yamada, Physica E, vol. 21, pp. 615, 2004.
8. Portavoce, I. Berbezier, and A. Ronda, Phys. Rev. B, vol. 69, pp. 155416, 2004.
9. J. Massies and N. Grandjean, Phys. Rev. B, vol. 48, pp. 8502, 1993.
10. B. R. Bennett, R. Magno, J. B. Boos, W. Kruppa and M. G. Ancona, Solid-State Electronics 49, 1875 (2005)
11. Brian R. Bennett, Brad P. Tinkham, and J. Brad Boos, Michael D. Lange and Roger Tsai, J. Vac. Sci. Technol B, 22, 688 (2004).
12. B. P. Tinkham, B. R. Bennett, R. Magno, B. V. Shanabrook, and J. B. Boos, J. Vac. Sci. Technol. B, 23, 1441 (2005).
13. L. Desplanque, D. Vignaud, X. Wallart. J Cryst Growth 301/302, 194 (2007). A. Portavoce, I. Berbezier, and A. Ronda, Materials and Engineering B., 101, 181 (2003).
14. X. Yang, J. B. Héroux, L. F. Mei, and W. I. Wang, Appl. Phys. Lett. 78, 4068 (2001)
15. J. B. Boos, W. Kruppa, B. R. Bennett, D. Park, S. W. Kirchhoefer, R. Bass and H.
B. Dietrich, IEEE Trans. on Electronic Devices, 45, 1869 (1998)
16. W. Kruppa, J. B. Boos, B. R. Bennett and B. P. Tinkham, Solid-State Electronics., 48, 2079 (2004)

We claim:

1. A method of forming an epitaxial semiconductor alloy on a substrate, comprising:
providing a substrate;
growing an Sb-containing buffer layer on the substrate, wherein the buffer layer comprises a first layer of AlₓGa₁₋ₓAsSb lattice matched to the substrate, and a second layer of Al(In)Sb lattice mismatched to the first layer, where x is selected from 1 to 0; and
growing a layer of As/Sb-containing semiconductor alloy on the buffer layer.

2. The method of claim 1, wherein the Al(In)Sb layer is lattice matched to the semiconductor alloy.

3. The method of claim 1, wherein the substrate is selected from the group consisting of: silicon, InP, GaAs, Ge and GaP.

4. The method of claim 1, wherein the semiconductor alloy contains a member of the 6.1 Å family.

5. The method of claim 1, wherein the buffer layer has a thickness of between about 0.2-3 μm.

6. The method of claim 5, wherein the buffer layer has a thickness of about 1 μm.

7. The method of claim 1, wherein the buffer layer has a thickness of 1 μm or below.

8. The method of claim 1, wherein the second layer thickness is from 0 to 3 μm.

9. The method of claim 1, wherein the semiconductor alloy comprises In, As and Sb.

10. The method of claim 9, wherein the semiconductor alloy is selected from the group consisting of: AlGaInAsSb, InAsSb, GaAsSb, InGaAsSb and InGaAlAsSbP.

11. The method of claim 1, wherein the semiconductor alloy has an electron mobility over 10,000 cm²/V-s.

12. The method of claim 1, wherein the substrate is InP, the Sb-containing buffer layer is AlGaAsSb/AlSb and the semiconductor alloy is InAsSb.

13. The method of claim 1, wherein the Sb-containing buffer layer is between 1000-20000 Å of AlSb and between 500-5000 Å of InAsSb.

14. A semiconductor device comprising:
a substrate;
an Sb-containing buffer layer overlying said substrate;
a layer of Sb-containing semiconductor alloy overlying said buffer layer.

15. The semiconductor device of claim 14, wherein the substrate is selected from the group consisting of: silicon, InP, GaAs, Ge and GaP.

16. The semiconductor device of claim 14, wherein the Sb-containing buffer layer comprises a layer of AlGa₁₋ₓAsSb and a layer of Al(In)Sb, wherein x is selected from 1 to 0.

17. The semiconductor device of claim 14, wherein the Sb-containing semiconductor alloy is selected from the group consisting of: AlGaInAsSb, InAsSb, GaAsSb, InGaAsSb and InGaAlAsSbP.

18. The semiconductor device of claim 14, wherein the substrate is InP, the Sb-containing buffer layer is AlGaAsSb/AlSb, and the semiconductor alloy is InAsSb.

19. A semiconductor substrate comprising:
an InP substrate;
a buffer layer comprising a layer of AlGaAsSb contacting the substrate and a layer of Al(In)Sb contacting the AlGaAsSb layer; and
an In- and Sb-containing semiconductor alloy contacting the Al(In)Sb layer.

20. The substrate of claim 19, wherein the substrate is InP, the Sb-containing buffer layer is AlGaAsSb/AlSb, and the semiconductor alloy is InAsSb.
